(19) United States
(12) Patent Application Publication
(10) Pub. No.: US 2026/0025964 A1
(43) Pub. Date: Jan. 22, 2026

(54) ELECTROMAGNETIC WAVE ABSORBING MEMBER

(71) Applicant: LINTEC Corporation, Tokyo (JP)

(72) Inventors: Masaya TODAKA, Tokyo (JP); Taiga MATSUSHITA, Tokyo (JP)

(21) Appl. No.: 18/995,045

(22) PCT Filed: Aug. 24, 2023
(86) PCT No.: PCT/JP2023/030517

§ 371 Date: Jan. 15, 2025

(30) Foreign Application Priority Data
Aug. 25, 2022 (JP) 2022-134106

(51) Int. Cl. H05K 9/00

(52) U.S. Cl. CPC H05K 9/0081

(57) ABSTRACT

An electromagnetic wave absorbing member (10) includes an electromagnetic wave absorbing layer (20), a spacer layer (30), and a reflective layer (40). The electromagnetic wave absorbing layer (20), the spacer layer (30), and the reflective layer (40) are laminated in this order. A relative permittivity of the spacer layer (30) is 5 or greater, and a melting point of the spacer layer (30) is 150° C. or higher.

### TECHNICAL FIELD

The present invention relates to an electromagnetic wave absorbing member.

The present application claims priority from the Japanese Patent Application No. 2022-134106, filed in Japan on Aug. 25, 2022, the contents of which are incorporated herein by reference.

### BACKGROUND ART

Sheet-shaped electromagnetic wave absorbing members that selectively absorb electromagnetic waves of a predetermined frequency are known. The electromagnetic wave absorbing member includes, for example, a first frequency selective shielding layer and a second frequency selective shielding layer. In such an electromagnetic wave absorbing member, fine line patterns of frequency selective surface (FSS) elements formed in the first frequency selective shielding layer and the second frequency selective shielding layer absorb electromagnetic waves of predetermined frequencies, respectively, and the electromagnetic wave absorbing member as a whole selectively shields electromagnetic waves with two different frequencies.

Depending on the application, the electromagnetic wave absorbing member is required to adhere to a curved surface when attached to the curved surface.

Patent Document 1 describes an electromagnetic wave absorbing member having the following characteristics (1) and (2) so as to be easily attached to a non-flat surface. Characteristic (1): A product of a Young's modulus of a magnetic layer and a thickness of the magnetic layer is from 0.1 MPa·mm to 1000 MPa·mm. Characteristic (2): A relative permittivity of the magnetic layer is from 1 to 10.

### CITATION LIST

### Patent Literature

Patent Document 1: JP 2019-4003 A

### SUMMARY OF INVENTION

### Technical Problem

However, although the electromagnetic wave absorbing member described in Patent Document 1 is excellent in curved surface conformability, it has a problem in that it is inferior in retaining electromagnetic wave absorption properties after a heat resistance test.

The present invention has been made in view of the above circumstances, and provides an electromagnetic wave absorbing member that is excellent in curved surface conformability and in retaining electromagnetic wave absorption properties after a heat resistance test.

### Solution to Problem

The present invention provides an electromagnetic wave absorbing member as follows.
[1] An electromagnetic wave absorbing member including:
   an electromagnetic wave absorbing layer;
   a spacer layer; and
   a reflective layer,
   in which
   the electromagnetic wave absorbing layer, the spacer layer, and the reflective layer are laminated in this order,
   a relative permittivity of the spacer layer is 5 or greater, and a melting point of the spacer layer is 150° C. or higher.
[2] The electromagnetic wave absorbing member according to [1], in which a thickness of the spacer layer is from 200 μm to 450 μm.
[3] The electromagnetic wave absorbing member according to [1] or [2], in which a Young's modulus of the spacer layer is 50 MPa or greater.
[4] The electromagnetic wave absorbing member according to any one of [1] to [3], in which a flexural rigidity is 300 N·mm² or less.

### Advantageous Effects of Invention

According to the present invention, it is possible to provide an electromagnetic wave absorbing member that is excellent in curved surface conformability and in retaining electromagnetic wave absorption properties after a heat resistance test.

### BRIEF DESCRIPTION OF DRAWINGS

FIG. 1 schematically illustrates an electromagnetic wave absorbing member according to an embodiment of the present invention in cross-section along a thickness direction.

FIG. 2 is a top view illustrating an example of an electromagnetic wave absorbing layer included in the electromagnetic wave absorbing member according to the embodiment of the present invention.

FIG. 3 is a schematic diagram illustrating a method for measuring flexural rigidity of the electromagnetic wave absorbing member according to the embodiment of the present invention.

### DESCRIPTION OF EMBODIMENTS

The present embodiment is specifically described in order to better understand the gist of the invention of the electromagnetic wave absorbing member according to the present invention. The present embodiment is not intended to limit the present invention unless otherwise specified.

In the present specification, “electromagnetic wave absorption pattern” refers to a collection of units having geometric figures and an object that selectively absorbs electromagnetic waves with frequencies within a specific range. It may be construed that “electromagnetic wave absorption pattern” has the same function as an antenna.

In the present specification, “electromagnetic waves in the millimeter wave region” refers to electromagnetic waves with wavelengths from 1 mm to 10 mm. “Electromagnetic waves in the millimeter wave region” also refers to electromagnetic waves with frequencies from 30 GHz to 300 GHz.

In the present specification, “from (a number) to (a number)”, which indicates a numerical range, includes the number after “from” as the lower limit of the numerical range and the number after “to” as the upper limit of the numerical range.

### Electromagnetic Wave Absorbing Member

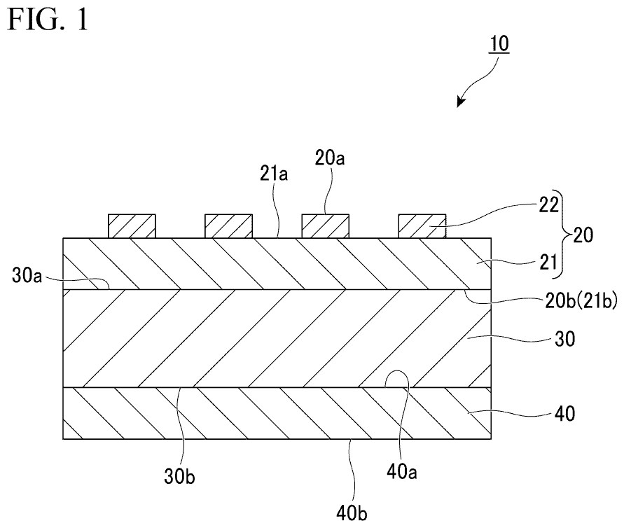

FIG. 1 schematically illustrates an electromagnetic wave absorbing member according to an embodiment of the present invention in cross-section along a thickness direction.

As illustrated in FIG. 1, an electromagnetic wave absorbing member 10 according to the embodiment includes an electromagnetic wave absorbing layer 20, a spacer layer 30, and a reflective layer 40. The electromagnetic wave absorbing layer 20, the spacer layer 30, and the reflective layer 40 are laminated in this order.

The reflective layer 40 is placed on another surface (back surface) 20b side of the electromagnetic wave absorbing layer 20. The spacer layer 30 is placed between the electromagnetic wave absorbing layer 20 and the reflective layer 40. That is, the electromagnetic wave absorbing layer 20 and the reflective layer 40 are laminated with the spacer layer 30 interposed therebetween.

The electromagnetic wave absorbing layer 20 may be a single layer, or may include a base 21 and an electromagnetic wave absorption pattern 22 formed on the base 21 as illustrated in FIG. 1.

When the electromagnetic wave absorbing layer 20 is a single layer, the electromagnetic wave absorbing layer 20 is made of the same material as the electromagnetic wave absorption pattern 22 described later.

In the electromagnetic wave absorbing member 10 according to the embodiment, the spacer layer 30 has a relative permittivity of 5 or greater, preferably 7 or greater, more preferably 8 or greater, and particularly preferably 9 or greater. When the spacer layer 30 has a relative permittivity of 5 or greater, a thickness of the spacer layer 30 can be made thin. This allows the electromagnetic wave absorbing member 10 to have excellent curved surface conformability.

The upper limit of the relative permittivity of the spacer layer 30 may be 30 or less, 25 or less, 20 or less, or 15 or less, from the viewpoint of preventing the Young's modulus of the spacer layer 30 from becoming too high.

The relative permittivity of the spacer layer 30 can be measured by a method described in an example below.

In the electromagnetic wave absorbing member 10 according to the embodiment, a melting point of the spacer layer 30 is 150° C. or higher, preferably 160° C. or higher, and more preferably 170° C. or higher. The melting point of the spacer layer 30 is a melting point of a material constituting of the spacer layer 30. When the melting point of the spacer layer 30 is less than the lower limit mentioned above, the relative permittivity of the spacer layer 30 changes after a heat resistance test, and performance of the spacer layer 30 deteriorates. The upper limit of the melting point of the spacer layer 30 may be 400° C. or below, 300° C. or below, 240° C. or below, or 190° C. or below, from the viewpoint of preventing the Young's modulus of the spacer layer 30 from becoming too high.

The melting point of the spacer layer 30 can be measured by a method described in the example below.

In the electromagnetic wave absorbing member 10 according to the embodiment, a thickness of the spacer layer 30 is preferably from 200 μm to 450 μm, more preferably from 250 μm to 400 μm, and particularly preferably from 300 μm to 340 μm. When the thickness of the spacer layer 30 is equal to or greater than the lower limit mentioned above, the spacer layer 30 tends to have a high relative permittivity. When the thickness of the spacer layer 30 is equal to or less than the upper limit mentioned above, flexural rigidity of the spacer layer 30 is low, and the curved surface conformability of the spacer layer 30 is improved.

When considering a wavelength shortening effect of the spacer layer 30, the thickness of the spacer layer 30 is appropriately changed according to the wavelength of an electromagnetic wave to be absorbed and the relative permittivity of the spacer layer 30.

When considering the wavelength shortening effect of the spacer layer 30, the thickness of the spacer layer 30 preferably satisfies Equation (1).

$$( Thickness of spacer layer 30 ) = ( λ ) \times ( 1 / 4 ) / {( ε )}^{1 / 2} \qquad Equation ( 1 )$$

In Equation (1), λ is a wavelength of an incoming electromagnetic wave, and ε is a relative permittivity of the spacer layer 30. The thickness of the spacer layer 30 may be adjusted as appropriate for an absorption characteristic. For example, the thickness of the spacer layer 30 can be changed in a range of 0.1 times to 3.0 times the thickness of the spacer layer 30 calculated from Equation (1).

When a relationship between the thickness of the spacer layer 30 and the wavelength λ satisfies Equation (1), the electromagnetic wave absorbing member 10 has a so-called λ/4 structure. This further increases a local maximum value of an absorption amount of electromagnetic waves absorbed by the electromagnetic wave absorbing member 10.

The thickness of the spacer layer 30 can be appropriately set in a range from 200 μm to 450 μm according to the wavelength λ of the electromagnetic wave to be absorbed.

The spacer layer 30 may be made of a high permittivity material. When the spacer layer 30 is a high permittivity layer, the thickness of the spacer layer 30 can be relatively thin.

When considering the permittivity of the spacer layer 30, the spacer layer 30 preferably contains at least one selected from the group consisting of barium titanate, titanium oxide, and strontium titanate.

The thickness of the spacer layer 30 can be measured by a constant pressured thickness measuring instrument manufactured by TECLOCK Co., Ltd.

The Young's modulus of the spacer layer 30 is preferably 1000 MPa or less, more preferably 600 MPa or less, and even more preferably 400 MPa or less. When the Young's modulus of the spacer layer 30 is equal to or less than the upper limit mentioned above, the curved surface conformability is improved. The lower limit of the Young's modulus of the spacer layer 30 may be 50 MPa or greater, 100 MPa or greater, or 200 MPa or greater, from the viewpoint of shape retention.

The Young's modulus of the spacer layer 30 can be measured in accordance with JIS K7127: 1999 “Plastics-Determination of tensile properties-Part 3: Test conditions for films and sheets”.

In the electromagnetic wave absorbing member 10 according to the embodiment, a flexural rigidity is preferably 240 N·mm² or less, more preferably 180 N·mm² or less, and even more preferably 100 N·mm² or less. When the flexural rigidity of the electromagnetic wave absorbing member 10 is equal to or less than the upper limit mentioned above, the curved surface conformability is improved. The lower limit of the flexural rigidity of the electromagnetic wave absorbing member 10 may be 10 N·mm² or greater, 30 N·mm² or greater, or 60 N·mm² or greater, from the viewpoint of shape retention.

The flexural rigidity of the electromagnetic wave absorbing member 10 can be measured by a method described in the example below.

A total thickness of the electromagnetic wave absorbing member 10 according to the embodiment (a total thickness from the outermost surface of the electromagnetic wave absorbing layer 20, i.e., a surface of the electromagnetic wave absorption pattern 22 (first surface (front surface) 20a of the electromagnetic wave absorbing layer 20) to a surface (second surface) 40b of the reflective layer 40 on an installation surface side) is preferably from 350 μm to 800 μm, more preferably from 400 μm to 600 μm, and particularly preferably from 450 μm to 520 μm, from the viewpoint of achieving both curved surface conformability and electromagnetic wave absorption properties.

### Electromagnetic Wave Absorbing Layer

The electromagnetic wave absorbing layer 20 consists of a frequency selective surface (FSS). The frequency selective surface is formed of a conductive member or the like and has a continuous structure with a shape equal to or smaller than a specific wavelength. The frequency selective surface may block only electromagnetic waves with specific frequencies.

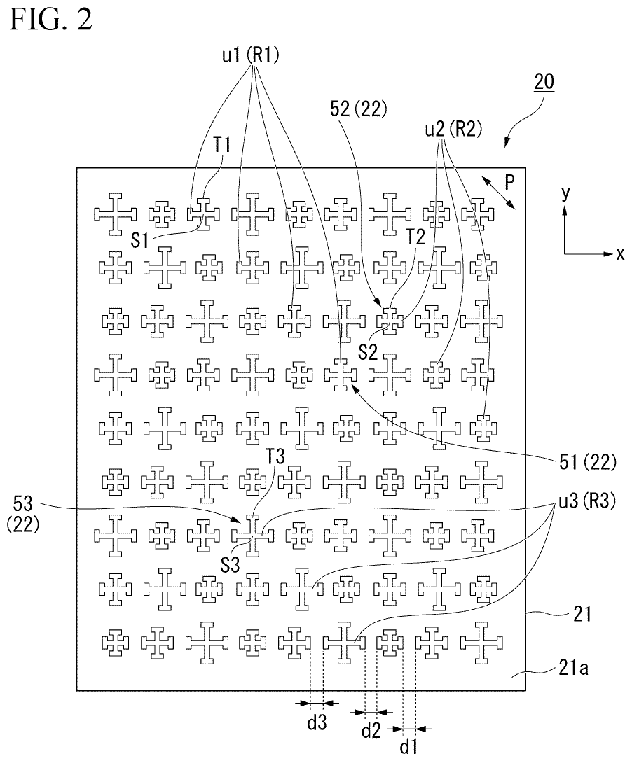

FIG. 2 is a top view illustrating an example of the electromagnetic wave absorbing layer according to the embodiment. As illustrated in FIG. 2, the electromagnetic wave absorbing layer 20 is an electromagnetic wave absorption film including the flat base 21 and the electromagnetic wave absorption pattern 22 formed on the first surface 21a of the base 21. The electromagnetic wave absorption pattern 22 includes a first electromagnetic wave absorption pattern 51, a second electromagnetic wave absorption pattern 52, and a third electromagnetic wave absorption pattern 53.

A Young's modulus of the electromagnetic wave absorbing layer 20 is preferably 10 GPa or less, more preferably 7 GPa or less, and even more preferably 5 GPa or less. When the Young's modulus is equal to or less than the upper limit mentioned above, the electromagnetic wave absorbing layer 20 has decreased flexural rigidity and improved curved surface conformability. The lower limit of the Young's modulus of the electromagnetic wave absorbing layer 20 may be 0.5 GPa or greater, may be 1 GPa or greater, or may be 3 GPa or greater, from the viewpoint of shape retention.

The Young's modulus of the electromagnetic wave absorbing layer 20 can be measured in accordance with JIS K7127: 1999 “Plastics-Determination of tensile properties-Part 3: Test conditions for films and sheets”.

### First Electromagnetic Wave Absorption Pattern

As illustrated in FIG. 2, the first electromagnetic wave absorption pattern 51 is composed of a plurality of first units u1. Each of the first units u1 has a geometric figure.

That is, the first electromagnetic wave absorption pattern 51 is a collection of the first units u1 having a geometric figure.

Each of the first units u1 functions as a single antenna. The first electromagnetic wave absorption pattern 51 may be, for example, a fine line pattern of an FSS element.

In the first electromagnetic wave absorption pattern 51, a plurality of first arrangements R1 are formed, in which the plurality of the first units u1 are arranged along a direction indicated by a double-headed arrow P in FIG. 2. It may be construed that the first electromagnetic wave absorption pattern 51 has the plurality of first arrangements R1. The first electromagnetic wave absorption pattern 51 can be constituted by formation of, on the base 21, the plurality of first arrangements R1 along the direction indicated by the double-headed arrow P at predetermined spacings.

The spacings between the plurality of first arrangements R1 are not particularly limited. The spacings between the first arrangements R1 may be regular or irregular.

As illustrated in FIG. 2, a shape of the first unit u1 is a cross shape with vertical and horizontal symmetry. Specifically, the first unit u1 has one cross portion S1 and four end portions T1. The cross portion S1 is composed of a linear portion parallel to the x-axis direction in FIG. 2 and a linear portion parallel to the y-axis direction in FIG. 2. The end portions T1 having a linear shape are each in contact with and perpendicular to each of both ends of the linear portion parallel to the x-axis direction or in contact with and perpendicular to each of both ends of the linear portion parallel to the y-axis direction.

By adjusting a length of the first unit u1 in the x-axis direction and a length of each of the four end portions T1 in the x-axis direction, an electromagnetic wave absorption characteristic of the first unit u1 that functions as a single antenna can be adjusted. The electromagnetic wave absorption characteristic can also be adjusted by adjustments in the y-axis direction in the same manner.

It should be noted that the shape of the first unit is not limited to a cross shape. The shape of the first unit is not limited, provided that it is an aspect in which the value of a frequency is to be A [GHz], where an absorption amount of electromagnetic waves absorbed by the first electromagnetic wave absorption pattern 51 exhibits its local maximum value at the frequency.

Examples of the shape of a figure for the first unit include a circular shape, an annular shape, a linear shape, a rectangular shape, a polygonal shape, an H shape, a Y shape, and a V shape.

In the electromagnetic wave absorbing layer 20, the shapes of the plurality of first units u1 are identical to each other. It should be noted that the shapes of the plurality of first units u1 do not need to be identical to each other. In other examples of the present invention, the shapes of the plurality of first units may be identical to or different from each other, as long as the absorption characteristic can be adjusted to a target frequency.

The first electromagnetic wave absorption pattern 51 selectively absorbs electromagnetic waves with a frequency of A [GHz]. The frequency value A [GHz] is a value of a frequency at which an absorption amount of electromagnetic waves absorbed by the first electromagnetic wave absorption pattern 51 exhibits its local maximum value in a range from 20 GHz to 110 GHz.

The frequency value A [GHz] at which an absorption amount of electromagnetic waves absorbed by the first electromagnetic wave absorption pattern 51 exhibits its local maximum value can be determined by, for example, Method X.

Method X: A standard film, which will be described below, is irradiated with electromagnetic waves while changing the frequency within a range from 20 GHz to 110 GHz, and the frequency of the electromagnetic waves at which an absorption amount of the electromagnetic waves absorbed by the standard film is maximum is designated as A [GHz].

The standard film has a planar standard base and a standard pattern formed at the standard base.

Details of the standard base can be the same as those of the base 21. Therefore, the details of the standard base will be described in the description of the base 21 below.

The standard pattern consists of only a plurality of standard units whose shapes are the figure identical to each other. It may be construed that the standard pattern, formed on the standard base of the standard film, consists of only one type of the figure having the identical shape. The standard pattern can be formed of a fine line pattern of an ordinary FSS element. Typically, the standard pattern is an electromagnetic wave absorption pattern identical to the first electromagnetic wave absorption pattern 51 (a shape identical to the unit u1).

The standard film has a plurality of standard units arranged on the standard base in a manner that spacings between the ends of the figures are 1 mm. For example, when the figure of the standard unit is a cross shape, the intersection of the cross is the center of the figure, and the ends of the figure are the portions furthest away from the center along each of the directions of the two linear portions constituting the cross.

A material of the standard units constituting the standard pattern is not limited, provided that it is an aspect in which the material allows an absorption amount of electromagnetic waves absorbed by the standard film to exhibit its maximum value when the standard film is irradiated with the electromagnetic waves while the frequency is changed within a range from 20 GHz to 110 GHz.

Details of the material of the standard unit can be identical to those of the first unit.

The absorption amount of electromagnetic waves absorbed by the standard film can be calculated using Equation (2).

$$Absorption Amount = Input Signal - Reflection Characteristic ( S 11 ) - Transmission Characteristic ( S 21 ) \qquad Equation ( 2 )$$

“Input signal” is an indicator of an intensity of an electromagnetic wave at an irradiation source when a standard film is irradiated with the electromagnetic wave.

“Reflection characteristic (S11)” is an indicator of an intensity of an electromagnetic wave reflected by a standard film when the standard film is irradiated with the electromagnetic wave by an irradiation source. Reflection characteristic (S11) can be measured, for example, by a free space method using a vector network analyzer.

“Transmission characteristic (S21)” is an indicator of an intensity of an electromagnetic wave that passes through a standard film when the standard film is irradiated with the electromagnetic wave by an irradiation source. Transmission characteristic (S21) can be measured, for example, by a free space method using a vector network analyzer.

The frequency A [GHz] can be determined, for example, by the following method.

First, a standard film is irradiated with electromagnetic waves while changing the frequency within a range from 20 GHz to 110 GHz, and the absorption amount of the electromagnetic waves absorbed by the standard film is calculated using Equation (2).

Subsequently, the frequency that has been changed is plotted on the horizontal axis, while the absorption amount calculated using Equation (2) is plotted on the vertical axis, hence creating an absorption spectrum chart. Typically, in this absorption spectrum chart, there is one value of the frequency on the horizontal axis at which the absorption amount reaches its maximum value. Thus, a single peak at which the absorption amount of the electromagnetic wave reaches its local maximum value is observed on the plot diagram. In this way, the frequency of the electromagnetic wave, at which the absorption amount of the electromagnetic wave exhibits its maximum value, can be designated as A [GHz].

In Method X, when the value of the frequency A can be predicted in advance, the frequency of the electromagnetic waves irradiating the standard film may be changed within a range narrower than the range from 20 GHz to 110 GHz. For example, the frequency of the electromagnetic waves irradiating the standard film may be changed within a range from 50 GHz to 110 GHz.

The first electromagnetic wave absorption pattern 51 absorbs electromagnetic waves having a frequency of A [GHz] determined by Method X.

For the electromagnetic wave absorbing layer 20 according to the embodiment, the frequency value A is preferably from 20 GHz to 110 GHz, more preferably from 60 GHz to 100 GHz, even more preferably from 65 GHz to 95 GHZ, and particularly preferably from 70 GHz to 90 GHz. When the frequency value A is within the numerical range mentioned above, the electromagnetic wave absorbing layer 20 can absorb electromagnetic waves in the millimeter wave region, and thus the electromagnetic wave absorbing layer 20 can be readily applied to automobile components, road peripheral members, building exterior wall related materials, windows, communication devices, radio telescopes, and the like.

A material of the first unit u1 is not limited as long as the absorption characteristic can be adjusted to a desired frequency.

Examples of the material of the first unit include a fine metal wire, a thin conductive film, and a fixed product of a conductive paste.

Examples of the metal include copper, aluminum, tungsten, iron, molybdenum, nickel, titanium, silver, gold, and an alloy containing two or more of the metals listed above (for example, steel such as stainless steel and carbon steel, brass, phosphor bronze, zirconium-copper alloy, beryllium-copper, iron-nickel, nichrome, nickel-titanium, kanthal, Hastelloy, and rhenium-tungsten).

Examples of a material of the thin conductive film include metal particles, carbon nanoparticles, and carbon fibers.

Spacings between the ends of the figures that are the first units u1 are not limited as long as the absorption characteristic can be adjusted to a desired frequency.

For example, the spacing between the ends of the figures that are the first units u1 may all be identical or may be different from each other. However, from the viewpoint that an electromagnetic wave absorption film that is less susceptible to the surrounding environment can be easily designed and, during production, precision of the frequency band of electromagnetic waves to be absorbed can be improved, the spacings between the ends of the figures that are the first units u1 are preferably identical to each other.

### Second Electromagnetic Wave Absorption Pattern

As illustrated in FIG. 2, the second electromagnetic wave absorption pattern 52 is composed of a plurality of second units u2.

The second electromagnetic wave absorption pattern 52 is formed in the same manner as the first electromagnetic wave absorption pattern 51.

The second electromagnetic wave absorption pattern 52 selectively absorbs electromagnetic waves with a frequency of B [GHz] that satisfies Equation (3). The frequency value B [GHz] is a value of a frequency when an absorption amount of electromagnetic waves absorbed by the second electromagnetic wave absorption pattern 52 exhibits its local maximum value. The frequency value B [GHz] satisfies Equation (3).

$$1.037 \times A \leq B \leq 1.3 \times A \qquad Equation ( 3 )$$

As shown in Equation (3), the second electromagnetic wave absorption pattern 52 absorbs electromagnetic waves with frequencies from 1.037×A [GHz] to 1.30×A [GHz]. The second electromagnetic wave absorption pattern 52 preferably absorbs electromagnetic waves with frequencies from 1.17×A [GHz] to 1.30×A [GHz].

The second electromagnetic wave absorption pattern 52 absorbs electromagnetic waves with frequencies of 1.037×A [GHz] or greater. Therefore, in a frequency band higher than A [GHz], the peak of an absorption amount of electromagnetic waves absorbed by the second electromagnetic wave absorption pattern 52 and the peak of the absorption amount of electromagnetic waves absorbed by the first electromagnetic wave absorption pattern 51 sufficiently overlap. As a result, compared to a film having the first electromagnetic wave absorption pattern 51 alone, the frequency band of electromagnetic waves that can be absorbed by the entire electromagnetic wave absorption film is extended to a frequency band higher than A [GHz].

The second electromagnetic wave absorption pattern 52 absorbs electromagnetic waves with frequencies of 1.30×A [GHz] or less. Therefore, in the frequency band higher than A [GHz], a difference in frequency between the peak of the absorption amount of electromagnetic waves absorbed by the second electromagnetic wave absorption pattern 52 and the peak of the absorption amount of electromagnetic waves absorbed by the first electromagnetic wave absorption pattern 51 is small. As a result, a single peak at which an absorption amount of electromagnetic waves absorbed by the entire electromagnetic wave absorption film reaches its local maximum value is observed.

As described above, the second electromagnetic wave absorption pattern 52 absorbs electromagnetic waves with frequencies from 1.037×A [GHz] to 1.30×A [GHz], and thus an absorption amount of electromagnetic waves absorbed by the entire electromagnetic wave absorption film is extended to a higher frequency band.

A material of the second units constituting the second electromagnetic wave absorption pattern 52 is not limited, provided that it is an aspect in which the material can absorb electromagnetic waves of B [GHz] and the absorption characteristic can be adjusted to the desired frequency.

Description of the material of the second unit is the same as that of the material of the first unit u1.

### Third Electromagnetic Wave Absorption Pattern

As illustrated in FIG. 2, the third electromagnetic wave absorption pattern 53 is composed of a plurality of third units u3.

The third electromagnetic wave absorption pattern 53 is formed in the same manner as the first electromagnetic wave absorption pattern 51.

The third electromagnetic wave absorption pattern 53 selectively absorbs electromagnetic waves with a frequency of C [GHz] that satisfies Equation (4). The frequency value C [GHz] is a value of a frequency at which an absorption amount of electromagnetic waves absorbed by the third electromagnetic wave absorption pattern 53 exhibits its local maximum value. The frequency value C [GHz] satisfies Equation (4).

$$0.6 \times A \leq C \leq 0.963 \times A \qquad Equation ( 4 )$$

As shown in Equation (4), the third electromagnetic wave absorption pattern 53 absorbs electromagnetic waves with frequencies from 0.60×A [GHz] to 0.963×A [GHz]. The third electromagnetic wave absorption pattern 53 preferably absorbs electromagnetic waves with frequencies from 0.60×A [GHz] to 0.83×A [GHz].

The third electromagnetic wave absorption pattern 53 absorbs electromagnetic waves with frequencies of 0.60×A [GHz] or greater. Therefore, in a frequency band lower than A [GHz], a difference in frequency between the peak of an absorption amount of electromagnetic waves absorbed by the third electromagnetic wave absorption pattern 53 and the peak of the absorption amount of electromagnetic waves absorbed by the first electromagnetic wave absorption pattern 51 is small. As a result, a single peak at which an absorption amount of electromagnetic waves absorbed by the entire electromagnetic wave absorbing layer 20 reaches its local maximum value is observed.

The third electromagnetic wave absorption pattern 53 absorbs electromagnetic waves with frequencies of 0.963×A [GHz] or less. Therefore, in the frequency band lower than A [GHz], the peak of the absorption amount of electromagnetic waves absorbed by the third electromagnetic wave absorption pattern 53 and the peak of the absorption amount of electromagnetic waves absorbed by the first electromagnetic wave absorption pattern 51 sufficiently overlap. As a result, compared to a film having the first electromagnetic wave absorption pattern 51 alone, the frequency band of electromagnetic waves that can be absorbed by the entire electromagnetic wave absorption film is extended to a frequency band lower than A [GHz].

As described above, the third electromagnetic wave absorption pattern 53 absorbs electromagnetic waves with frequencies from 0.60×A [GHz] to 0.963×A [GHz], and thus an absorption amount of electromagnetic waves absorbed by the entire electromagnetic wave absorbing layer 20 is extended to a lower frequency band.

A material of the third units u3 constituting the third electromagnetic wave absorption pattern 53 is not limited, provided that it is an aspect in which the material can absorb electromagnetic waves of C [GHz] and the absorption characteristic can be adjusted to the desired frequency.

Description of the material of the third unit u3 is the same as that of the material of the first unit u1.

In the electromagnetic wave absorbing layer 20 illustrated in FIG. 2, the first arrangements R1, the second arrangements R2, and the third arrangements R3 are arranged adjacent to each other along a direction indicated by the double-headed arrow P. Thus, the first arrangements R1, the second arrangements R2, and the third arrangements R3 are arranged adjacent to each other on the base 21. Therefore, the frequency band of electromagnetic waves selectively absorbed by the second electromagnetic wave absorption pattern 52 and the frequency band of electromagnetic waves selectively absorbed by the third electromagnetic wave absorption pattern 53 overlap based on the frequency value A [GHz] of electromagnetic waves selectively absorbed by the first electromagnetic wave absorption pattern 51 at the peak position. As a result, the absorption band of electromagnetic waves absorbed by the entire electromagnetic wave absorbing layer 20 can be easily extended to both the higher frequency side and the lower frequency side based on the frequency value A [GHz] at the peak position.

A spacing d1 between the first unit u1 and the second unit u2, a spacing d2 between the second unit u2 and the third unit u3, a spacing d3 between the third unit u3 and the first unit u1, each as illustrated in FIG. 2, may be identical to or different from each other.

The spacing d1 may be, for example, from 0.2 mm to 4 mm, from 0.3 mm to 2 mm, or from 0.5 mm to 1 mm.

The spacing d2 may be, for example, from 0.2 mm to 4 mm, from 0.3 mm to 2 mm, or from 0.5 mm to 1 mm.

The spacing d3 may be, for example, from 0.2 mm to 4 mm, from 0.3 mm to 2 mm, or from 0.5 mm to 1 mm.

When the spacing d1, the spacing d2, and the spacing d3 are within the aforementioned numerical ranges, the absorption band of electromagnetic waves absorbed by the entire electromagnetic wave absorbing layer 20 can be more easily extended based on the frequency value A [GHz] at the peak position.

In the electromagnetic wave absorbing layer 20, shapes of the first units u1 are identical to each other, shapes of the second unit u2 are identical to each other, and shapes of the third unit u3 are identical to each other. It should be noted that the shapes of the first units u1 do not need to be the figures identical to each other, the second units u2 do not need to be the figures identical to each other, and the third units u3 do not need to be the figures identical to each other. That is, in other examples of the present invention, the shapes of the first units u1 may be identical to or different from each other, the shapes of the second units u2 may be identical to or different from each other, and the shapes of the third units u3 may be identical to or different from each other.

The base 21 is not limited as long as it is planar and is in a form that allows the first electromagnetic wave absorption pattern 51, the second electromagnetic wave absorption pattern 52, and the third electromagnetic wave absorption pattern 53 to be formed on the first surface 21a. The base 21 may have a single-layer structure or a multi-layer structure.

A thickness of the base 21 may be, for example, 5 μm to 500 μm, 15 μm to 200 μm, or 25 μm to 100 μm.

A thickness of the first electromagnetic wave absorption pattern 51, a thickness of the second electromagnetic wave absorption pattern 52, and a thickness of the third electromagnetic wave absorption pattern 53 are not limited. These thicknesses can be changed as desired depending on the desired characteristic. These three thicknesses may be identical to or different from each other, and are preferably identical in consideration of productivity. The thickness of each of the first electromagnetic wave absorption pattern 51, the second electromagnetic wave absorption pattern 52, and the third electromagnetic wave absorption pattern 53 is preferably from 0.1 μm to 300 μm, more preferably from 1 μm to 150 μm, and particularly preferably from 10 μm to 80 μm from the viewpoint of achieving both electromagnetic wave absorption properties and curved surface conformability.

A material of the base 21 can be appropriately selected according to the application of the electromagnetic wave absorbing member 10.

For example, the base 21 may be made of a transparent material for the purpose of providing transparency to the electromagnetic wave absorbing member 10. Alternatively, the base 21 may be made of a flexible material for the purpose of providing the electromagnetic wave absorbing member 10 with curved surface conformability. A surface of the base 21 may be smoothed for the purpose of improving the transparency and three-dimensional formability of the electromagnetic wave absorbing member 10.

For example, the base 21 can be made of resin. The resin may be a thermoplastic resin or a thermosetting resin. However, from the viewpoint of the three-dimensional formability of the electromagnetic wave absorbing member 10, the base 21 preferably contains a thermoplastic resin.

Examples of the thermoplastic resin include a polyolefin resin, a polyester resin, a polyester-polyether resin, a polyacrylic resin, a polystyrene resin, a polyimide resin, a polyimide amide resin, a polyamide resin, a polyurethane resin, a polycarbonate resin, a polyarylate resin, a melamine resin, an epoxy resin, a urethane resin, a silicone resin, and a fluororesin.

Specific examples of the polyolefin resin include polypropylene and polyethylene. Specific examples of the polyester resin include polyethylene terephthalate, polybutylene terephthalate, and polyethylene naphthalate.

The base 21 may contain an optional component as long as the effects of the present invention are not impaired. Examples of the optional component include, for example, an inorganic filler, a colorant, a curing agent, an antioxidant, a photostabilizer, a flame retardant, a conductive agent, an antistatic agent, and a plasticizer.

From the viewpoint of further improvement in the electromagnetic wave absorption performance of the electromagnetic wave absorbing member 10, the thickness, permittivity, electrical conductivity, and magnetic permeability of the base 21 can be set as appropriate.

When the electrical properties of electromagnetic waves to be absorbed are taken into consideration, the base 21 may be a high-permittivity layer. When the base 21 is a high-permittivity layer, a thickness of the electromagnetic wave absorbing member 10 can be relatively thin.

The electromagnetic wave absorbing layer 20 can be produced by, for example, the following method.

First, a base 21 is prepared. Subsequently, a first electromagnetic wave absorption pattern 51, a second electromagnetic wave absorption pattern 52, and a third electromagnetic wave absorption pattern 53 are formed on the first surface 21a of the base 21.

Each of the electromagnetic wave absorption patterns is formed such that a value of a frequency, at which an absorption amount of electromagnetic waves absorbed by each of the electromagnetic wave absorption patterns exhibits its local maximum value, is a predetermined value [GHz].

The order in which the respective electromagnetic wave absorption patterns are formed is not limited. The respective electromagnetic wave absorption patterns may be formed in the same process or may be formed in separate processes.

A method for forming each of the electromagnetic wave absorption patterns is not particularly limited, provided that it is an aspect that the method allows formation of a predetermined frequency. Examples of a method for forming each of the electromagnetic wave absorption patterns include the following methods.

A printing method in which, using a conductive paste, each of the electromagnetic wave absorption patterns is printed on the first surface 21a of the base 21.

A development method in which each of the electromagnetic wave absorption patterns is developed on the first surface 21a of the base 21.

A method in which a thin metal film is provided on the first surface 21a of the base 21 by sputtering, vacuum deposition, or lamination of metal foil, and then a pattern of the thin metal film is formed on the first surface 21a of the base 21 by photolithography.

A method disposing a metal wire on the first surface 21a of the base 21.

### Spacer Layer

The spacer layer 30 is provided on the second surface 21b of the base 21 of the electromagnetic wave absorbing layer 20.

The spacer layer 30 has two surfaces, 30a and 30b. The one surface 30a of the spacer layer 30 faces the second surface 21b of the base 21. The reflective layer 40 is provided at the other surface 30b of the spacer layer 30.

The spacer layer 30 may have a single-layer structure or a multi-layer structure.

A material of the spacer layer 30 can be appropriately selected according to the application. For example, when used for the exterior of an automobile, it is preferable to select a material that has curved surface conformability and excellent heat resistance.

Examples of the flexible material include a plastic film, a nonwoven fabric, and a rubber sheet. Among these, a plastic film is preferable from the viewpoint of easy kneading with filler.

Specific examples of resin constituting the plastic film include thermoplastic resins with high melting points selected from the thermoplastic resins described above for the base 21.

The spacer layer 30 may contain filler. The filler may be any filler having a high permittivity, and examples thereof include barium titanate, strontium titanate, calcium titanate, and titanium oxide.

A content of the filler in the spacer layer 30 is preferably from 20 vol % to 60 vol %, more preferably from 25 vol % to 50 vol %, and particularly preferably from 30 vol % to 45 vol %. When the content of the filler exceeds the upper limit mentioned above, the resin may become brittle, making it difficult to manufacture the spacer layer 30. When the content of the filler is less than the lower limit mentioned above, a thickness of the spacer layer 30 required to provide the required electromagnetic wave absorption properties may become too large, and the curved surface conformability may not be provided.

The two surfaces 30a and 30b of the spacer layer 30 are each preferably provided with an adhesive layer. Thus, the electromagnetic wave absorbing layer 20 and the reflective layer 40 can be easily attached to the two surfaces 30a and 30b, respectively.

The details and preferred aspects of the adhesive layer may be the same as those described for the adhesive layer in the reflective layer below.

### Reflective Layer

The reflective layer 40 has two surfaces 40a and 40b. The first surface 40a of the reflective layer 40 faces the second surface 30b of the spacer layer 30.

The reflective layer 40 is not limited as long as the reflective layer 40 is one that is capable of reflecting electromagnetic waves that arrive at a surface of the electromagnetic wave absorbing member 10 and pass through the electromagnetic wave absorbing member 10. Some of the electromagnetic waves that arrive at the electromagnetic wave absorbing member 10 are reflected by the electromagnetic wave absorbing layer 20 or absorbed by the electromagnetic wave absorbing layer 20. Meanwhile, electromagnetic waves that are neither reflected nor absorbed by the electromagnetic wave absorbing layer 20 pass through the electromagnetic wave absorbing layer 20. The electromagnetic waves that have passed through the electromagnetic wave absorbing layer 20 are reflected by the reflective layer 40 toward the electromagnetic wave absorbing layer 20.

For example, when the reflective layer 40 is electrically conductive in a surface direction of either of the two surfaces 40a and 40b, the reflective layer 40 can reflect the electromagnetic waves that have passed through the electromagnetic wave absorbing layer 20. To be specific, metal foil such as aluminum foil or copper foil, or a metal plate such as a copper plate, can be laminated to a resin film such as a polyethylene terephthalate film to be used as the reflective layer 40. Instead of the metal foil or the metal plate, a transparent conductive film such as an ITO film, or a mesh sheet formed of a metal wire can be used. Among these, a metal plate is preferred from the viewpoint of high electrical conductivity.

In consideration of the reflection characteristic of the reflective layer 40, a metal wire, a conductive yarn, a twisted yarn including a metal wire and a conductive yarn, or a thin conductive film may be provided on the second surface 40b of the reflective layer 40. The thin conductive film can be provided on the surface 40b by, for example, a printing method such as screen printing, gravure printing, or inkjet printing; sputtering or vacuum deposition; or photolithography.

A Young's modulus of the reflective layer 40 is preferably 6 GPa or less, more preferably 5.5 GPa or less, and even more preferably 5 GPa or less. When the Young's modulus of the reflective layer 40 is equal to or less than the upper limit mentioned above, the curved surface conformability is improved. The lower limit of the Young's modulus of the reflective layer 40 may be 0.5 GPa or greater, 1 GPa or greater, or 3 GPa or greater.

The Young's modulus of the reflective layer 40 can be measured in accordance with JIS K7127: 1999 “Plastics-Determination of tensile properties-Part 3: Test conditions for films and sheets”.

When the spacer layer 30 is formed on an object having electrical conductivity, such as a metal, the object having electrical conductivity, such as a metal, serves as the reflective layer 40. Therefore, the reflective layer 40 can be omitted.

For the purpose of application of the electromagnetic wave absorbing member 10 to surfaces of various articles, an adhesive layer may be provided on the second surface 40b of the reflective layer 40. When an adhesive layer is provided on the second surface 40b of the reflective layer 40, a release film may be provided on a surface of the adhesive layer opposite to a surface in contact with the surface 40b. The release film is removed when the electromagnetic wave absorbing member 10 is in use. When the release film covers the adhesive surface, handling during distribution becomes easier.

Examples of the adhesive constituting the adhesive layer include a heat seal type adhesive that is activated by heat; an adhesive that is activated by moisture; and a pressure-sensitive adhesive that is activated by pressure. Among these, from the viewpoint of convenience, a pressure-sensitive adhesive is preferable.

Specific examples of the pressure-sensitive adhesive include an acrylic-based pressure-sensitive adhesive, a urethane-based pressure-sensitive adhesive, a rubber-based pressure-sensitive adhesive, a polyester-based pressure-sensitive adhesive, a silicone-based pressure-sensitive adhesive, and a polyvinyl ether-based pressure-sensitive adhesive. Among these, at least one selected from the group consisting of an acrylic-based pressure-sensitive adhesive, a urethane-based pressure-sensitive adhesive, and a rubber-based pressure-sensitive adhesive is preferable, and an acrylic-based pressure-sensitive adhesive is more preferable.

The electromagnetic wave absorbing member 10 according to the embodiment may also include a protective layer formed on the first surface (front surface) 20a of the electromagnetic wave absorbing layer 20.

The protective layer is not limited as long as it is one that is capable of protecting the electromagnetic wave absorbing layer 20.

Since the relative permittivity of the spacer layer 30 is 5 or greater and the melting point of the spacer layer 30 is 150° C. or higher, the electromagnetic wave absorbing member 10 according to the embodiment is excellent in curved surface conformability and in retaining the electromagnetic wave absorption properties after a heat resistance test. When resin having a low melting point is used for the spacer layer, the thickness of the spacer layer and the distribution of the filler contained in the spacer layer change during a heat resistance test, resulting in reduced electromagnetic wave absorption properties.

The electromagnetic wave absorbing member 10 according to the embodiment has excellent shape retention because the Young's modulus of the spacer layer 30 is 50 MPa or greater. Here, “having excellent shape retention” means that the film thickness does not change even when subjected to thermal influences or physical influences, and thus the electromagnetic wave absorption properties do not change.

### EXAMPLES

The present invention will be described in further detail below with reference to examples and comparative examples, but the present invention is not limited to these examples below.

### Example 1

### Production of Electromagnetic Wave Absorbing Member

An electromagnetic wave absorbing member was produced as described below.

Copper was deposited onto a base, which is a PET film (trade name: PET50A4160, manufactured by Toyobo Co., Ltd.) having a thickness of 50 μm, to form a copper thin film.

Thereafter, the copper thin film was patterned into an electromagnetic wave absorption pattern by photolithography to form an electromagnetic wave absorption pattern as illustrated in FIG. 2, resulting in the formation of an electromagnetic wave absorbing layer including an electromagnetic wave absorption pattern. A thickness of the electromagnetic wave absorption pattern was 20 μm.

Subsequently, a polyester-polyether copolymer (trade name: P-55B, manufactured by Toyobo Co., Ltd.) as resin and barium titanate (trade name: BT-UP2, manufactured by Nippon Chemical Industrial Co., Ltd.) as filler were kneaded at 200° C. and 40 rpm for 5 minutes using a Labo Plastomill (model name: 4C150, manufactured by Toyo Seiki Seisaku-sho, Ltd.) to prepare a mixed material having a barium titanate content of 40 vol %.

The above mixed material was pressed at 200° C. for 3 minutes using a hydraulic hot press (model name: SA-302, manufactured by TESTER SANGYO CO., LTD.), resulting in the formation of a spacer layer having a thickness of 300 μm.

As a material for a pressure sensitive adhesive layer, an acrylic copolymer having a weight-average molecular weight of 800000 and consisting of 70 mass % of 2-ethylhexyl acrylate, 29 mass % of n-butyl acrylate, 0.5 mass % of acrylic acid, and 0.5 mass % of 2-hydroxyethyl acrylate was prepared. An acrylic pressure sensitive adhesive solution was prepared by adding 1 part by mass (solids content equivalent) of an isocyanate-based cross-linking agent and 8 parts by mass of an ultraviolet absorber (trade name: Tinuvin 477, manufactured by BASF Japan Ltd.) to 100 parts by mass (solids content equivalent) of the acrylic copolymer, and diluting the mixture with ethyl acetate.

Subsequently, the above acrylic pressure sensitive adhesive solution was coated on a release film, dried at 90° C. for 1 minute and then cured at room temperature for 1 week, resulting in the formation of a pressure sensitive adhesive layer having a thickness of 20 μm.

Subsequently, the above pressure sensitive adhesive layer was laminated to one surface of the spacer layer.

Subsequently, as a reflective layer, Metal-Me TS (a film formed by depositing aluminum on a PET film) manufactured by Toray Advanced Film Co., Ltd. having a thickness of 50 μm was prepared, and both surfaces of this film were laminated so as to be covered with the pressure sensitive adhesive layers. That is, a laminate of release film/pressure sensitive adhesive layer/reflective layer/pressure sensitive adhesive layer/release film was formed.

Subsequently, the release film on an aluminum deposited side of the reflective layer was removed, and the exposed pressure sensitive adhesive layer on the aluminum deposited side of the reflective layer was placed in a position facing a surface of the spacer layer opposite to a surface to be an electromagnetic wave absorbing layer side.

Subsequently, the release film on the electromagnetic wave absorbing layer side of the spacer layer was removed, and the exposed pressure sensitive adhesive layer was laminated to a surface of the electromagnetic wave absorbing layer opposite to a surface on which the electromagnetic wave absorption pattern was formed, resulting in the formation of an electromagnetic wave absorbing member with pressure sensitive adhesive layers.

### Example 2

An electromagnetic wave absorbing member with pressure sensitive adhesive layers of Example 2 was formed in the same manner as in Example 1 except that a content of barium titanate in a mixed material for producing the spacer layer was 35 vol % and a thickness of the spacer layer was 350 μm.

### Example 3

An electromagnetic wave absorbing member with pressure sensitive adhesive layers of Example 3 was formed in the same manner as in Example 1 except that polyester (manufactured by Bell Polyester Products Inc.) was used as resin and a thickness of the spacer layer was 360 μm.

### Example 4

An electromagnetic wave absorbing member with pressure sensitive adhesive layers of Example 4 was formed in the same manner as in Example 1 except that a content of barium titanate in a mixed material for producing the spacer layer was 25 vol % and a thickness of the spacer layer was 425 μm.

### Comparative Example 1

An electromagnetic wave absorbing member with pressure sensitive adhesive layers of Comparative Example 1 was formed in the same manner as in Example 1 except that resin contained in a mixed material for producing the spacer layer was an ethylene-vinyl acetate copolymer resin (EVA, manufactured by Dow-Mitsui Polychemicals Co., Ltd.), a content of barium titanate in the mixed material was 45 vol %, and a thickness of the spacer layer was 300 μm.

### Comparative Example 2

An electromagnetic wave absorbing member with pressure sensitive adhesive layers of Comparative Example 2 was formed in the same manner as in Example 1 except that resin contained in a mixed material for producing the spacer layer was low density polyethylene (LDPE, manufactured by Japan Polystyrene Inc.), a content of barium titanate in the mixed material was 20 vol %, and a thickness of the spacer layer was 470 μm.

### Evaluation

The electromagnetic wave absorbing members of Examples 1 to 4 and Comparative Examples 1 and 2 were subjected to the following evaluations. The results are indicated in Table 1.

### Evaluation of Relative Permittivity

Relative permittivities of the spacer layers formed in the examples and the comparative examples were measured using a microwave dielectrometer (40 GHz TE mode) manufactured by AET, Inc. and a network analyzer (model name: MS4612 B) manufactured by Anritsu Corporation.

### Measurement of Young's Modulus (Modulus of Elasticity in Tension)

The electromagnetic wave absorbing layer, the spacer layer, and the reflective layer were cut into test pieces of 15 mm long×150 mm wide, and a modulus of elasticity in tension E was measured in accordance with JIS K7127: 1999 “Plastics-Determination of tensile properties-Part 3: Test conditions for films and sheets”. To be specific, the above test pieces were subjected to a tensile test using a tensile tester (product name: Autograph AG-IS 500N, manufactured by

Shimadzu Corporation) at a speed of 200 mm/min after setting a distance between chucks to 100 mm, and the modulus of elasticity in tension (MPa) of each of the electromagnetic wave absorbing layer, the spacer layer, and the reflective layer was measured.

### Measurement of Melting Point

A melting point of the spacer layer was measured using a DSC (model name: Q2000) manufactured by TA Instruments. The measurement conditions were set as follows.
Temperature rise: 20° C./min
Measurement temperature range: −50° C. to 250° C.

### Heat Resistance Evaluation

The spacer layer was tested for heat resistance using a high temperature and constant humidity chamber (model name: PHH-102) manufactured by ESPEC Corp. The temperature of the high temperature and constant humidity chamber was set to 120° C., and the spacer layer was placed in the high temperature and constant humidity chamber for 240 hours. The relative permittivity of the spacer layer was measured after the spacer layer was taken out from the high temperature and constant humidity chamber, and a change before and after the test was evaluated.

### Evaluation of Curved Surface Conformability

The electromagnetic wave absorbing member were attached to curved surfaces having different diameters, and the curved surface conformability of the electromagnetic wave absorbing member was evaluated.

The minimum diameter (mm) of the curved surface on which the electromagnetic wave absorbing member can be attached without appearance defects such as wrinkles or edge lifting was evaluated.

### Evaluation of Flexural Rigidity

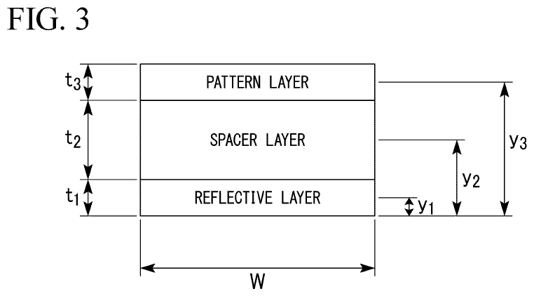

Flexural rigidity of the electromagnetic wave absorbing member was calculated using FIG. 3 and Equation (11).

In FIG. 3, a position of the centroid of the electromagnetic wave absorbing member was y_{c} and a width of the electromagnetic wave absorbing member was W. Further, thicknesses of the electromagnetic wave absorbing layer, the spacer layer, and the reflective layer were t₁, t₂, and t₃, respectively, and heights to the centers of the respective layers were y₁, y₂, and y₃.

Respective areas (A₁, A₂, and A₃) of the electromagnetic wave absorbing layer, the spacer layer, and the reflective layer and an entire area A and y₁, y₂, and y₃ were calculated from Equations (11) to (17).

$${A}_{1} = W \times {t}_{1} \qquad ( 11 )$$

$${A}_{2} = W \times {t}_{2} \qquad ( 12 )$$

$${A}_{3} = W \times {t}_{3} \qquad ( 13 )$$

$$A = {A}_{1} + {A}_{2} + {A}_{3} \qquad ( 14 )$$

$${y}_{1} = {t}_{1} / 2 \qquad ( 15 )$$

$${y}_{2} = {t}_{1} + {t}_{2} / 2 \qquad ( 16 )$$

$${y}_{3} = {t}_{1} + {t}_{2} + {t}_{3} / 2 \qquad ( 17 )$$

Using the values obtained from Equations (11) to (17), the centroid ye of the electromagnetic wave absorbing member was calculated from Equation (18).

$${y}_{c} = ( {A}_{1} {y}_{1} + {A}_{2} {y}_{2} + {A}_{3} {y}_{3} ) / A \qquad ( 18 )$$

Here, the second moments of area I₁, I₂, and I₃, and I_{c1}, I_{c2}, and I_{c3} with respect to the centroids of the respective layers were calculated from Equations (20) to (25).

$${I}_{1} = ( W \times {{t}_{1}}^{3} ) / 12 \qquad ( 20 )$$

$${I}_{2} = ( W \times {{t}_{2}}^{3} ) / 12 \qquad ( 21 )$$

$${I}_{3} = ( W \times {{t}_{3}}^{3} ) / 12 \qquad ( 22 )$$

$${I}_{c 1} = {I}_{1} + {A}_{1} \times {( {y}_{c} - {y}_{1} )}^{2} \qquad ( 23 )$$

$${I}_{c 2} = {I}_{2} + {A}_{2} \times {( {y}_{c} - {y}_{2} )}^{2} \qquad ( 24 )$$

$${I}_{c 3} = {I}_{3} + {A}_{3} \times {( {y}_{c} - {y}_{3} )}^{2} \qquad ( 25 )$$

The second moment of area I of the electromagnetic wave absorbing member was calculated from Equation (26), and the flexural rigidity of the electromagnetic wave absorbing member was calculated from Equation (27).

$$I = {I}_{c 1} + {I}_{c 2} + {I}_{c 3} \qquad ( 26 )$$

$$Flexural rigidity ( N \cdot {mm}^{2} ) = E ( N / {mm}^{2} ) \times I ( {mm}^{4} ) \qquad ( 27 )$$

### Evaluation of Return Loss

The electromagnetic wave absorbing member was tested for heat resistance using a high temperature and constant humidity chamber (model name: PHH-102) manufactured by ESPEC Corp. The temperature of the high temperature and constant humidity chamber was set to 120° C., and the electromagnetic wave absorbing member was placed in the high temperature and constant humidity chamber for 240 hours. Return loss of the electromagnetic wave absorbing member was measured after being taken out from the high temperature and constant humidity chamber, and a change before and after the test was evaluated.

The return loss was measured by the free space method.

TABLE 1

| | | | | | | | Comparative | Comparative |
|---|---|---|---|---|---|---|---|---|
| | | | Example 1 | Example 2 | Example 3 | Example 4 | Example 1 | Example 2 |
| Electromagnetic | Material of electromagnetic wave | | Copper deposition | | | | | |
| wave absorbing | absorption pattern | | | | | | | |
| layer | Material of base | | PET | | | | | |
| | Young's modulus of electromagnetic | | 4500 | | | | | |
| | wave absorbing layer (MPa) | | | | | | | |
| Spacer layer | Resin | Material | Polyester- | Polyester- | Polyester | Polyester- | EVA | LDPE |
| | | | polyether | polyether | | polyether | | |
| | | | copolymer | copolymer | | copolymer | | |
| | | Young's modulus (MPa) | 93 | 93 | 320 | 93 | 60 | 200 |
| | | Melting point (° C.) | 180 | 180 | 200 | 180 | 90 | 120 |
| | | Relative permittivity | 2.7 | 2.7 | 2.5 | 2.7 | 2.3 | 2.1 |

| | | |
|---|---|---|
| Filler | Filler type | Barium titanate |

| | | | | | | |
|---|---|---|---|---|---|---|
| Addition amount (vol %) | 40 | 35 | 35 | 25 | 45 | 20 |

| | Initial relative permittivity | 10 | 7.5 | 7 | 5 | 10 | 4 |
|---|---|---|---|---|---|---|---|
| | Relative permittivity after heat | 10 | 7.5 | 7 | 5 | 9.5 | 3.8 |
| | resistance test | | | | | | |
| | Thickness (μm) | 300 | 350 | 360 | 425 | 300 | 470 |
| | Young's modulus (MPa) | 390 | 330 | 500 | 290 | 350 | 400 |
| Reflective | Material of base | PET | | | | | |
| layer | Young's modulus of reflective layer | 4500 | | | | | |
| | (MPa) | | | | | | |

| | | | | | | |
|---|---|---|---|---|---|---|
| Flexural rigidity of electromagnetic wave absorbing | 70 | 90 | 200 | 120 | 50 | 250 |
| member (N · mm²) | | | | | | |
| Curved surface conformability | 80 | 90 | 150 | 100 | 70 | 180 |
| Initial return loss (dB) | −20 | −20 | −20 | −20 | −20 | −20 |
| Return loss after heat resistance test (dB) | −20 | −20 | −20 | −20 | −5 | −10 |

From the results shown in Table 1, it was found that the electromagnetic wave absorbing members of Example 1 to Example 4 were excellent in curved surface conformability and in retaining electromagnetic wave absorption properties after the heat resistance test.

On the other hand, it was found that the electromagnetic wave absorbing member of Comparative Example 1 was inferior in retaining electromagnetic wave absorption properties after the heat test.

It was found that the electromagnetic wave absorbing member of Comparative Example 2 was inferior in curved surface conformability and in retaining electromagnetic wave absorption properties after the heat resistance test.

### INDUSTRIAL APPLICABILITY

The electromagnetic wave absorbing member according to the present invention can be suitably used as an electromagnetic wave absorbing member for transportation equipment such as automobiles.

### REFERENCE SIGNS LIST

10 Electromagnetic wave absorbing member
20 Electromagnetic wave absorbing layer
21 Base
22 Electromagnetic wave absorption pattern
30 Spacer layer
40 Reflective layer
51 First electromagnetic wave absorption pattern
52 Second electromagnetic wave absorption pattern
53 Third electromagnetic wave absorption pattern

1. An electromagnetic wave absorbing member comprising:
an electromagnetic wave absorbing layer;
a spacer layer; and
a reflective layer,
wherein
the electromagnetic wave absorbing layer, the spacer layer, and the reflective layer are laminated in this order,
a relative permittivity of the spacer layer is 5 or greater, and
a melting point of the spacer layer is 150° C. or higher.

2. The electromagnetic wave absorbing member according to claim 1, wherein a thickness of the spacer layer is from 200 μm to 450 μm.

3. The electromagnetic wave absorbing member according to claim 1, wherein a Young's modulus of the spacer layer is 50 MPa or greater.

4. The electromagnetic wave absorbing member according to claim 1, wherein a flexural rigidity is 300 N·mm² or less.
